(19) United States
(12) Patent Application Publication
(10) Pub. No.: US 2022/0407216 A1
(43) Pub. Date: Dec. 22, 2022

(54) IN-PACKAGE MMWAVE ANTENNAS AND LAUNCHERS USING GLASS CORE TECHNOLOGY

(71) Applicant: Intel Corporation, Santa Clara, CA (US)

(72) Inventors: Georgios C. DOGIAMIS, Chandler, AZ (US); Telesphor KAMGAING, Chandler, AZ (US); Neelam PRABHU GAUNKAR, Chandler, AZ (US); Aleksandar ALEKSOV, Chandler, AZ (US); Veronica STRONG, Hillsboro, OR (US)

(21) Appl. No.: 17/354,891

(22) Filed: Jun. 22, 2021

(51) Int. Cl. H01Q 1/22; H05K 1/02; H01Q 9/04; H01Q 13/02; H01L 23/498; H01L 21/48

(52) U.S. Cl. CPC H01Q 1/2283; H05K 1/0237; H01Q 9/0407; H01Q 13/02; H01L 23/49827; H01L 21/486; H05K 2201/10098

(57) ABSTRACT

Embodiments disclosed herein include package substrates with antennas on the core. In an embodiment, a package substrate comprises a core with a first surface and a second surface. In an embodiment, a first conductive plane is formed into the core, where the first conductive plane is substantially orthogonal to the first surface, and a second conductive plane is formed into the core, where the second conductive plane is substantially orthogonal to the first surface. In an embodiment, an antenna is on the core, where the antenna is between the first conductive plane and the second conductive plane.

### TECHNICAL FIELD

Embodiments of the present disclosure relate to electronic packages, and more particularly to package substrates with a glass core and mm-wave antennas and launchers integrated with the glass core.

### BACKGROUND

With a surge in demand for high-speed communication services, low latency solutions with high data rates and bandwidth density have emerged. To meet the requirements of higher bandwidth density millimeter wave, sub-Terahertz (THz) or RF frequencies are employed to develop high speed wired or wireless interconnect systems. Such solutions employ a combination of active mmWave/sub-THz transceivers with RF/mmWave passives such as filters, capacitors or inductors and RF/mmWave antennas or signal launchers enabling larger bandwidths and higher data rates. Several of such passive components are implemented on package instead of the die due to lower losses in organic substrates at millimeter wave and sub-THz frequencies.

However, existing on-package implementations are limited in some ways due to limits on minimum achievable traces specifications (trace width and/or trace spacings), minimum via drill and via pad dimensions, and process tolerances. Additionally, traditional organic packaging substrates are limited in that they cannot produce non-vertically oriented planes, nor can they produce antennas that are fabricated with non-uniform substrate thicknesses tightly spaced on a common substrate. Additionally, it is difficult to provide isolation for the antennas, especially for sub-THz applications. Ceramic based packages are similarly limited. Some proposals have included the use of machined metal components for antenna structures. However, such components are heavy, bulky, and expensive.

### BRIEF DESCRIPTION OF THE DRAWINGS

FIG. 1A is a cross-sectional illustration of a glass core with top and bottom surfaces that are being exposed with a laser, in accordance with an embodiment.

FIG. 1B is a cross-sectional illustration of the glass core with regions that have their morphology altered by the laser, in accordance with an embodiment.

FIG. 1C is a cross-sectional illustration of the glass core with a via hole through a thickness of the glass core, in accordance with an embodiment.

FIG. 1D is a cross-sectional illustration of the glass core with a via through the thickness of the glass core, in accordance with an embodiment.

FIG. 2A is a plan view illustration of the glass core with a plurality of circular vias, in accordance with an embodiment.

FIG. 2B is a plan view illustration of the glass core with a vertical via plane, in accordance with an embodiment.

FIG. 3A is a cross-sectional illustration of a package core with a plurality of antennas that are isolated from each other by vertically oriented planes, in accordance with an embodiment.

FIG. 3B is a plan view of the package core that illustrates the length of the planes, in accordance with an embodiment.

FIG. 3C is a cross-sectional illustration of a package core with a plurality of antennas that are isolated from each other by vertically oriented planes that do not pass through an entire thickness of the core, in accordance with an embodiment.

FIG. 3D is a cross-sectional illustration of a package core with a plurality of antennas that are isolated from each other by vertically oriented planes that have hourglass shaped cross-sections.

FIG. 4A is a cross-sectional illustration of a package core with a plurality of antennas that are provided in recesses with different depths, in accordance with an embodiment.

FIG. 4B is a cross-sectional illustration of a package core with a plurality of antennas that are provided in recesses with different depths and with vertical via planes between the antennas, in accordance with an embodiment.

FIG. 4C is a cross-sectional illustration of a package core with a plurality of antennas that are provided in recesses with different depths and with vertical via planes between the antennas, where cross-sections of the via planes are hourglass shaped, in accordance with an embodiment.

FIG. 5 is a cross-sectional illustration of a package core with monopole antennas that are arranged to provide cloaking structures, in accordance with an embodiment.

FIG. 6A is a cross-sectional illustration of a package core with a horn antenna with a sloped ring plane through the core, in accordance with an embodiment.

FIG. 6B is a plan view illustration of the package core in FIG. 6A, where the horn antenna is a rectangular ring, in accordance with an embodiment.

FIG. 6C is a plan view illustration of the package core in FIG. 6A, where the horn antenna is a circular ring, in accordance with an embodiment.

FIG. 6D is a plan view illustration of the package core in FIG. 6A, where the horn antenna is a rectangular ring with cutouts, in accordance with an embodiment.

FIG. 7A is a cross-sectional illustration of an electronic package with a core that comprises antennas that are isolated by vertically oriented planes, in accordance with an embodiment.

FIG. 7B is a cross-sectional illustration of an electronic package with a core that comprises antennas that are isolated by vertically oriented planes and a buildup layer between the core and the dies, in accordance with an embodiment.

FIG. 7C is a cross-sectional illustration of an electronic package with a core that comprises antennas that are isolated by vertically oriented planes, and a base die that couples together a plurality of second dies, in accordance with an embodiment.

FIG. 7D is a cross-sectional illustration of an electronic package with a core that comprises antennas that are isolated by vertically oriented planes, in accordance with an embodiment.

FIG. 8 is a cross-sectional illustration of an electronic system that comprises a package superstrate with a core that includes antennas that are separated by vertically oriented planes, in accordance with an embodiment.

FIG. 9 is a schematic of a computing device built in accordance with an embodiment.

### EMBODIMENTS OF THE PRESENT DISCLOSURE

Described herein are package substrates with a glass core and mm-wave antennas and launchers integrated with the glass core, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, antenna architectures are currently limited when implemented on organic package substrates or ceramic package substrates. Accordingly, embodiments disclosed herein include antenna or launcher architectures that are fabricated on substrates that are suitable for patterning with a laser-assisted etching process. Generally, laser-assisted etching processes involve exposing the core to a laser. The laser exposure results in a change in the morphology of the exposed regions. For example, in a glass core, the structure may turn from amorphous to crystalline after exposure by the laser. The change in structure allows for selective etching of the exposed regions. After etching, conductive material may be disposed in the openings.

The laser-assisted etching process allows for the formation of crack free, high-density via holes and planes into the core substrate. Whereas existing through core vias (e.g., PTHs) have diameters of 100 μm or larger and pitches of 250 μm or larger, the laser-assisted etching process may enable hole diameters and plane thicknesses that are approximately 50 μm or smaller and pitches that are approximately 40 μm or larger. Diameters of the holes and thicknesses of planes may be able to be approximately 10 μm without masks, and potentially as small as 2 μm when a hardmask is also used. The thickness of the core may also be between approximately 100 μm and 1,000 μm. Though it is to be appreciated that embodiments may also apply to larger and/or smaller hole diameters, plane thicknesses, pitches, and core substrate thicknesses.

In addition to the small pitches and feature sizes enabled by the laser-assisted etching process, embodiments allow for improved antenna isolation. Particularly, vertically oriented via planes may be provided between antennas. As such, the individual antennas in an array can be effectively isolated from each other by providing a ground surface between each antenna. The laser assisted etching process also allows for precision etching of recesses into the core substrate. For example, a recess may be etched to a target depth with an accuracy of several micrometers. Since the antenna bandwidth depends on the underlying substrate thickness, such structures support multi-band operation of an antenna array.

Furthermore, laser-assisted etching processes enable structures that are non-vertical. For example, angling the laser relative to a surface of the core substrate during the exposure allows for features that are non-orthogonal to the surface of the substrate core. Such non-vertical structures may be used to enable certain antenna architectures, such as, for example, horn antennas.

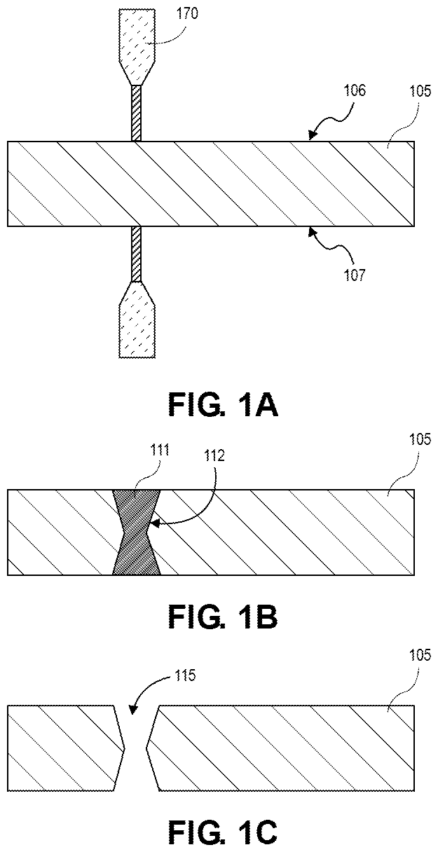

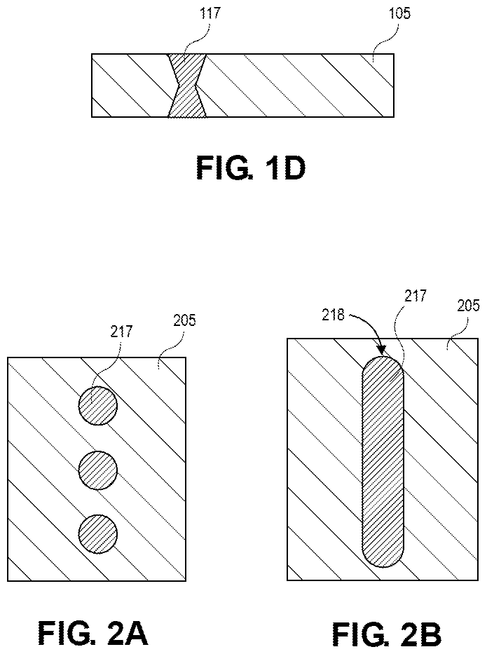

Referring now to FIGS. 1A-1D, a series of cross-sectional illustrations depicting a process for forming a hole in a core substrate 105 using a laser-assisted etching process is shown, in accordance with an embodiment. In FIGS. 1A-1D, the hole is shown in a single cross-section. However, it is to be appreciated that the hole may be extended to form trenches suitable for the formation of vertically oriented planes in addition to standard vias. The ability to form both vias and vertically oriented planes allows for the formation of isolated antenna architectures, such as, but not limited to patch antennas, double patch antennas, monopole antennas, and horn antennas. Particularly, vertically oriented planes may be provided between antennas to provide the desired isolation.

As shown in FIG. 1A, the core substrate 105 is exposed by a laser 170. The laser 170 may be irradiated over both a first surface 106 and a second surface 107. However, the laser 170 may only irradiate a single surface of the core substrate 105 in other embodiments. In order to form a trench for a vertically oriented plane, the laser 170 may be scanned across the surface of the core substrate 105. In FIG. 1A, the laser 170 is oriented orthogonally with the first surface 106. However, it is to be appreciated that the laser 170 may be tilted so that the laser exposes the core substrate 105 at a non-orthogonal angle. Such angled exposures enable the formation of non-vertically oriented planes and the like, as will be described in greater detail below.

In an embodiment, the core substrate 105 may comprise a material that is capable of forming a morphological change as a result of the exposure by the laser 170. For example, in the case of a glass core substrate 105, the morphological change may result in the conversion of an amorphous crystal structure to a crystalline crystal structure. While glass is used as an example here, it is to be appreciated that the core substrate 105 may also comprise ceramic materials, silicon, or other non-conductive semiconductor materials. In an embodiment, the core substrate 105 may have a thickness between the first surface 106 and the second surface 107 that is between 100 μm and 1,000 μm. However, it is to be appreciated that larger or smaller thicknesses may also be used for the core substrate 105 in other embodiments.

Referring now to FIG. 1B, a cross-sectional illustration of the core substrate 105 after the morphological change has occurred is shown, in accordance with an embodiment. As shown, an exposed region 111 is provided through a thickness of the core substrate 105. In an embodiment, the exposed region 111 may have sidewalls 112 that are sloped. That is, the sidewalls 112 may not be substantially vertical (with respect to the first surface 106 and the second surface 107). In a particular embodiment, the exposed region 111 may have an hourglass shaped cross-section that results from exposure from laser exposure on both the first surface 106 and the second surface 107. As used herein, an hourglass shaped cross section may refer to a shape that starts with a first width on a first end, decreases in width while moving away from the first end until reaching a minimum width between the first end and a second end, and increasing in width while moving from the minimum width in the middle towards the second end. That is, the shape may have a middle region that is narrower in width than the widths of the opposing ends. In an embodiment, the sidewalls 112 may have a slope that is approximately 10° or less away from vertical. While shown with sloped sidewalls 112, it is also to be appreciated that embodiments may include substantially vertical sidewalls depending on the laser parameters and the material of the core substrate 105.

In FIG. 1B, the exposed region 111 extends through an entire thickness of the core substrate 105. However, it is to be appreciated that blind features may also be formed with the laser-assisted etching process. As used herein, a blind feature refers to a feature that extends into, but not through, the thickness of a substrate. In the case of a blind feature, the laser parameters are chosen so than the morphological change of the exposed region 111 extends partially into, but not through, a thickness of the core substrate 105. It is to be appreciated that control of the laser parameters can provide a depth to the blind feature that is accurate to within a few microns.

Referring now to FIG. 1C, a cross-sectional illustration of the core substrate 105 after the exposed region 111 is removed to form a hole 115 through the core substrate 105 is shown, in accordance with an embodiment. Similarly, in the case of forming a vertically oriented plane, a trench may be formed instead of a hole 115. In an embodiment, the hole 115 may be formed with an etching process that is selective to the exposed region 111 over the remainder of the core substrate 105. The etch selectivity of the exposed region 111 to the remainder of the core substrate 105 may be 10:1 or greater, or 50:1 or greater. That is, while selective to the exposed region 111, some portion of the core substrate 105 may also be etched, resulting in the thickness of the core substrate 105 being slightly reduced. In an embodiment, the etchant may be a wet etching chemistry.

Referring now to FIG. 1D, a cross-sectional illustration of the core substrate 105 after a via 117 is formed in the hole 115 is shown, in accordance with an embodiment. In the case of a hole 115 that is extended into a trench, the via 117 may instead be a vertically oriented plane. In an embodiment, the via 117 may be deposited with a plating process or any other suitable deposition process.

In an embodiment, the hole 115 may have a maximum diameter that is approximately 100 μm or less, approximately 50 μm or less, or approximately 10 μm or less. The pitch between individual holes 115 in the core substrate 105 may be between approximately 10 μm and approximately 100 μm in some embodiments. The small diameters and pitch (compared to traditional PTH vias that typically have diameters that are 100 μm or larger and pitches that are 100 μm or larger) allow for high density integration of vias and vertically oriented planes.

In FIGS. 1A-1D only a single cross-section of the core substrate 105 is shown for simplicity. However, it is to be appreciated that the shape of the vias 117 may take substantially any form. This is because the laser providing the morphological change in the core substrate 105 may be moved in a controllable manner. Examples of various plan views of a vias 217 in a core substrate 205 are shown in FIGS. 2A and 2B.

Referring now to FIG. 2A, a plan view illustration of a core substrate 205 with a plurality of circular vias 217 is shown, in accordance with an embodiment. While three vias 217 are shown, it is to be appreciated that any number of vias 217 may be provided in any configuration. Referring now to FIG. 2B, a plan view illustration of a core substrate 205 with a via 217 that is extended along one direction to form a vertically oriented plane is shown, in accordance with an embodiment. Such a structure 217 may be referred to herein as a “via plane” or simply a “plane”. The plane 217 may have a thickness through the core substrate 205 that is substantially uniform, while also being extended in a direction, as opposed to having a width and length that are substantially uniform. As shown in FIG. 2B, the ends of the plane 217 may be rounded surfaces 218. The rounded surfaces may be the result of the shape of the laser irradiation. That is, the focus of the laser may be substantially circular in some embodiments. In FIG. 2B, the plane 217 is shown as a straight line. However, it is to be appreciated that the via plane 217 may also include turns (e.g., to form a conductive shell).

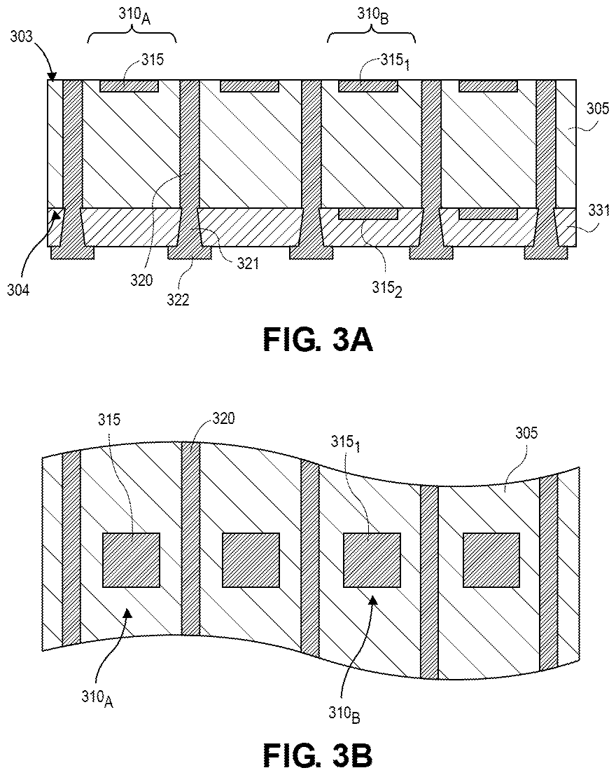

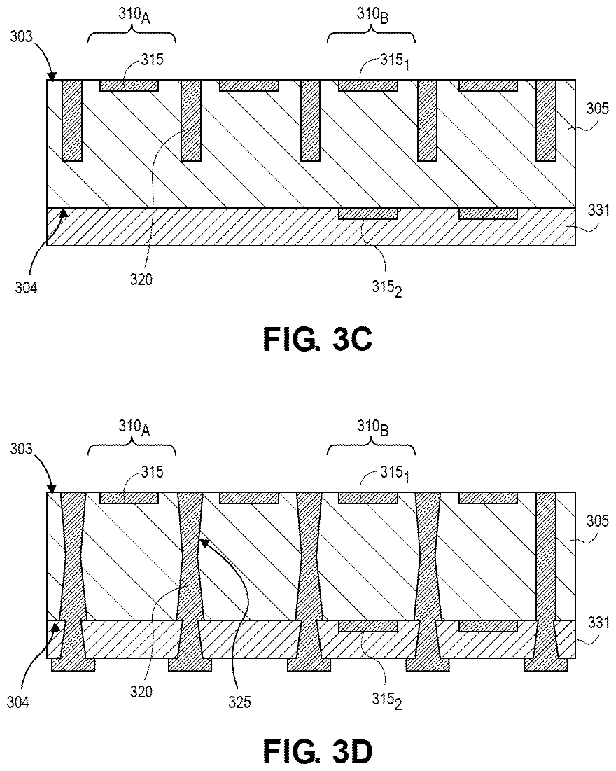

Referring now to FIG. 3A, a cross-sectional illustration of a core 305 is shown, in accordance with an embodiment. The core 305 may be a glass core 305 or any other suitable material that is patternable with a laser-assisted etching process, such as the one described in greater detail above. The core 305 may comprise a first surface 303 and a second surface 304. In an embodiment, a buildup layer 331 may be provided over the second surface 304. While not shown, it is to be appreciated that a buildup layer 331 may also be provided over the first surface 303. Additionally, FIG. 3A would imply that the die is ultimately attached to pads 322 on the second surface 304. However, it is to be appreciated that the die may optionally be attached over the first surface 303 by depopulating some antennas 310 or by placing the die next to the array of antennas.

In an embodiment, an array of antennas 310 may be provided on the core 305. In the illustrated embodiment, patch antennas 310A and stacked patch antennas 310E are shown. The patch antenna 310A comprises a patch 315 on the first surface 303 of the core. In the illustrated embodiment, the patch 315 is embedded in the core 305. In other embodiments, the patch 315 may be on the first surface 303 so that no part of the patch 315 is within the core 305. In an embodiment, the stacked patch antenna 310E comprises a first patch 315₁ on the first surface 303 of the core 305 and a second patch 315₂ on the second surface 304 of the core 305. In the illustrated embodiments, the first patch 315₁ is embedded in the core 305. However, in other embodiments, the first patch 315₁ may be on the first surface 303. The second patch 315₂ is on the second surface 304 of the core 305, but it is to be appreciated that the second patch 315₂ may be embedded in the core 305. In yet another embodiment, other passive matching structures, or even more patches can be integrated into the buildup layers 331. Additionally, it is even possible to include patch architectures on die side back-end-of-line (BEOL) layers.

While two examples of different antenna architectures are shown in FIG. 3A, it is to be appreciated that the array of antennas 310 may include a single type of antenna architecture. Additionally, while the examples of a patch antenna 310A and a stacked patch antenna 310E are shown in FIG. 3A, it is to be appreciated that the array of antennas 310 may include any type of antenna architecture. For example, monopole antennas or horn antennas may also be used. Examples of a monopole antenna architecture and a horn antenna architecture are provided in greater detail below.

In an embodiment, a plurality of vertically oriented planes 320 may be embedded in the core 305. In an embodiment, each of the antennas 310 may be positioned between a pair of vertically oriented planes 320. That is, each antenna 310 is separated from an adjacent antenna by a vertically oriented plane 320. In an embodiment, the vertically oriented planes 320 may be configured to be held at a ground potential. As such, the vertically oriented planes 320 may be referred to as ground planes in some embodiments. In an embodiment, the vertically oriented ground planes are referred to as being vertical because they are substantially orthogonal to the first surface 303 and the second surface 304 of the core 305.

In an embodiment, the vertically oriented planes 320 may pass through an entire thickness of the core 305. That is, the vertically oriented planes 320 may extend from the first surface 303 to the second surface 304 of the core 305. In an embodiment, the vertically oriented planes 320 may be electrically coupled to a pad 322 on a surface of the buildup layer 331 by a via 321 through the buildup layer 331.

Referring now to FIG. 3B, a plan view illustration of a portion of the core 305 is shown, in accordance with an embodiment. As shown, the vertically oriented planes 320 extend laterally past edges of the patches 315 and 315₁. In FIG. 3B, electrical connections to the patches 315 are not shown for simplicity. In some embodiments, the patches may be capacitively coupled to a signal source, and there may not be any direct electrical connection to the patches 315 and 315₁. Additionally, embodiments may further comprise vertically oriented planes 320 that would run from left to right in FIG. 3B. As such, the patches 315 may be surrounded on all sides by a vertically oriented plane 320.

Referring now to FIG. 3C, a cross-sectional illustration of a core 305 with an array of antennas 310 is shown, in accordance with an additional embodiment. In an embodiment, the core 305 in FIG. 3C may be substantially similar to the core 305 in FIG. 3A, with the exception of the vertically oriented planes 320 are blind features. That is, the vertically oriented planes 320 begin at the first surface 303 and extend into, but not through, the core 305. As noted above, the depth control of the vertically oriented planes 320 may be accurate to within a few microns. It is to be understood that a mix of blind and thru feature can be present in some embodiments.

In the illustrated embodiment, the vertically oriented planes 320 are provided into the first surface 303. However, it is to be appreciated that the vertically oriented planes 320 may alternatively be provided into the second surface 304. That is, the vertically oriented planes 320 may be on the surface of the core 305 opposite from the patches 315 in the case of a single patch antenna 310A.

Referring now to FIG. 3D, a cross-sectional illustration of a core 305 with an array of antennas 310 is shown, in accordance with an additional embodiment. In an embodiment, the core 305 in FIG. 3D may be substantially similar to the core 305 in FIG. 3A, with the exception of the cross-section of the vertically oriented planes 320. As shown in FIG. 3D, the sidewalls 325 of the vertically oriented planes 320 may be sloped. For example, the sidewalls 325 may be sloped so as to form an hourglass shaped cross-section for the vertically oriented planes 320. The hourglass shaped cross-section may be characteristic of the laser-assisted etching process. While an hourglass shaped cross-section is shown, it is to be appreciated that embodiment disclosed herein include vertically oriented planes 320 with any sloping sidewalls 325.

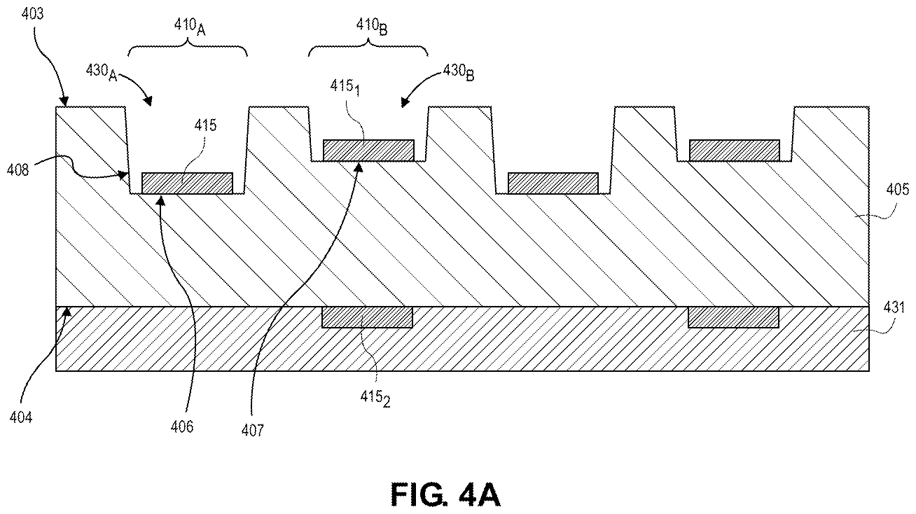

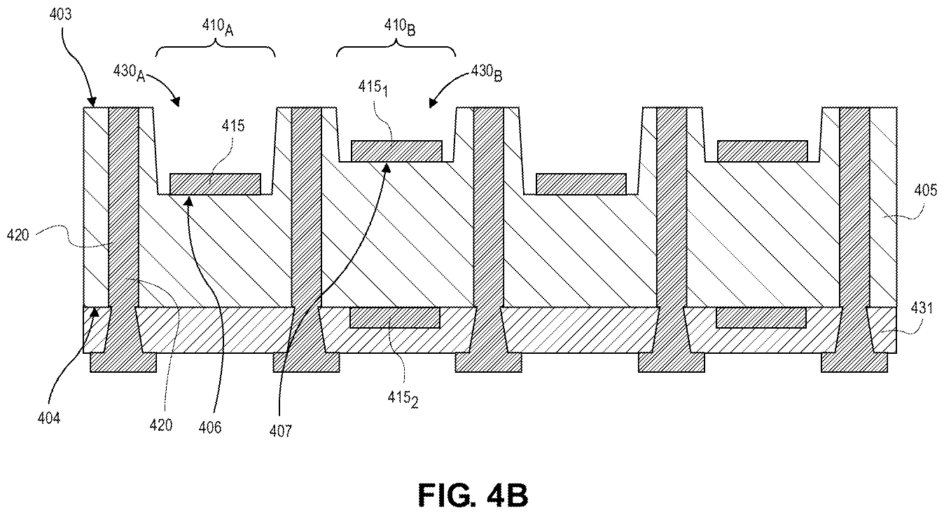

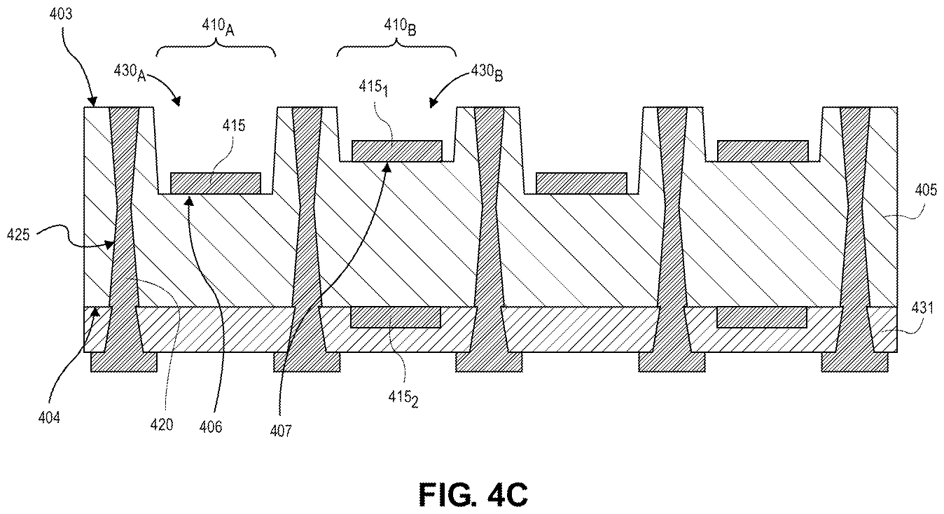

Referring now to FIG. 4A, a cross-sectional illustration of a core 405 with an array of antennas 410 is shown, in accordance with an embodiment. In an embodiment, the core 405 may be a material suitable for laser-assisted etching processes, such as a glass core 405. The core 405 has a first surface 403 and a second surface 404. A buildup layer 431 may be provided over the second surface 404.

In an embodiment, the array of antennas 410 may include first antennas 410A and second antennas 410B. The first antennas 410A may be patch antennas with a patch 415, and the second antennas 410E may be stacked patch antennas with a first patch 415₁ and a second patch 415₂ on the second surface 404. In other embodiments, a single type of antenna may be included in the array of antennas 410. In yet another embodiment, other types of antennas (e.g., monopole antennas, horn antennas, etc.) may be substituted for the patch antennas.

In an embodiment, the patches 415 and first patches 415₁ may be provided in recesses 430 into the first surface 403. For example, patches 415 are on a recessed surface 406 in a first recess 430A, and patches 415₁ are on a recessed surface 407 in a second recess 430B. In an embodiment, the recesses 430 may be fabricated with a laser-assisted etching process. Due to the laser-assisted etching process, sidewalls 408 of the recesses 430 may be sloped.

In an embodiment, the recesses 430A and 430B may have different depths. As such, the thickness of the core 405 underlying the different antennas 410 may be different. Since the antenna bandwidth depends on the underlying core thickness, such recess structures support multi-band operation of an antenna array with antennas supporting different bandwidths and/or different center frequency of operation (for addressing different frequency bands). The ability to fine tune the depth of the recesses 430 allows for the independent trimming/designing of each antenna 410 to operate at a given band. In the illustrated embodiment, two different depths of the recesses 430 are shown. In other embodiments, more than two different depths may be used. Additionally, a single depth may be used for all of the recesses. In such an embodiment, the other antennas 410 may be provided on the first surface 403 of the core 405 (without any recess) in order to provide different underlying substrate thicknesses.

In FIG. 4A, the recesses 430 are substantially unfilled. That is, the recesses 430 may be considered to be “air filled”. In other embodiments, the remaining space in the recesses 430 may be filled with a dielectric material. For example, a low loss dielectric material may fill the recesses 430. In an embodiment, the dielectric material may be a different material than the core 405.

Referring now to FIG. 4B, a cross-sectional illustration of a core 405 is shown, in accordance with an additional embodiment. In an embodiment, the core 405 in FIG. 4B may be substantially similar to the core 405 in FIG. 4A, with the addition of vertically oriented planes 420 between the antennas 410. In an embodiment, the vertically oriented planes 420 may extend from the first surface 403 of the core 405 to the second surface 404 of the core 405. In other embodiments, the vertically oriented planes 420 may be blind features that do not extend through the entire thickness of the core 405. As shown, each antenna 410 may be positioned between a pair of the vertically oriented planes 420. The vertically oriented planes 420 may be ground planes 420 to provide electromagnetic shielding for each of the antennas 410.

Referring now to FIG. 4C, a cross-sectional illustration of a core 405 is shown, in accordance with an additional embodiment. In an embodiment, the core 405 may be substantially similar to the core 405 in FIG. 4B with the exception of the cross-section of the vertically oriented planes 420. Instead of having substantially vertical sidewalls, the sidewalls 425 shown in FIG. 4C have sloped surfaces. In a particular embodiment, the sloped sidewalls 425 provide an hourglass shaped cross-section to the vertically oriented planes 420. The hourglass shaped cross-section may be characteristic of the laser-assisted etching process used to fabricate the vertically oriented planes 420. In some embodiments (e.g., when the vertically oriented planes 420 are blind features), the sidewalls 425 may have a single slope, and provide a trapezoidal shaped cross-section.

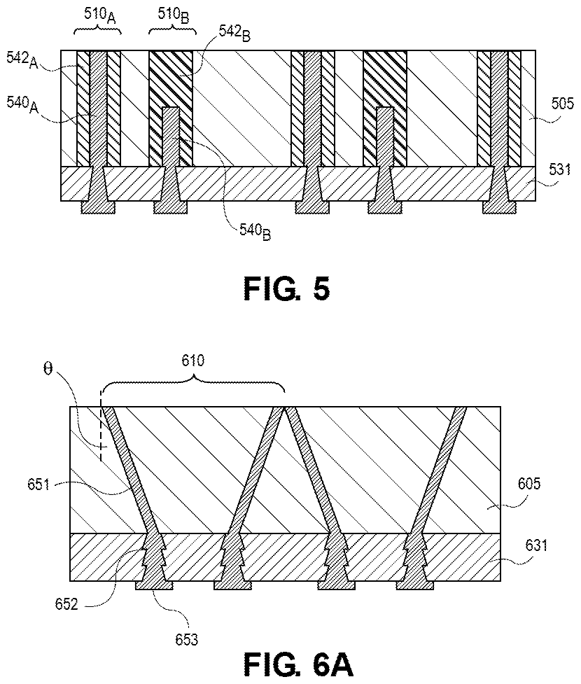

Referring now to FIG. 5, a cross-sectional illustration of a core 505 with monopole antennas 510 is shown, in accordance with an embodiment. In an embodiment, first antennas 510_{A} may include a monopole 540_{A} that extends through a thickness of the core 505, and second antennas 510_{B} may include a monopole 540_{B} that extends only partially through a thickness of the core 505. The monopoles 540_{A} may be embedded in a first dielectric 542A and the monopoles 540_{B} may be embedded in a second dielectric 542_{B}. In an embodiment, the array of antennas 510 may be arranged in order to generate a cloaking structure. The cloaking functionality may allow for first antennas 510_{A} to operate unaffected by the array of second antennas 510_{B}, and vice versa. While a single cloaking structure is shown in FIG. 5, it is to be appreciated that laser-assisted etching processes may also be used to form other antenna arrays that employ cloaking functionality.

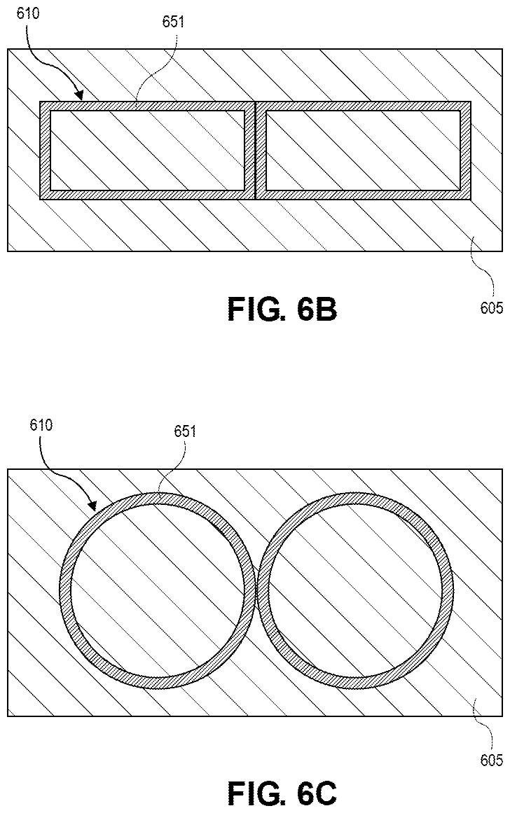

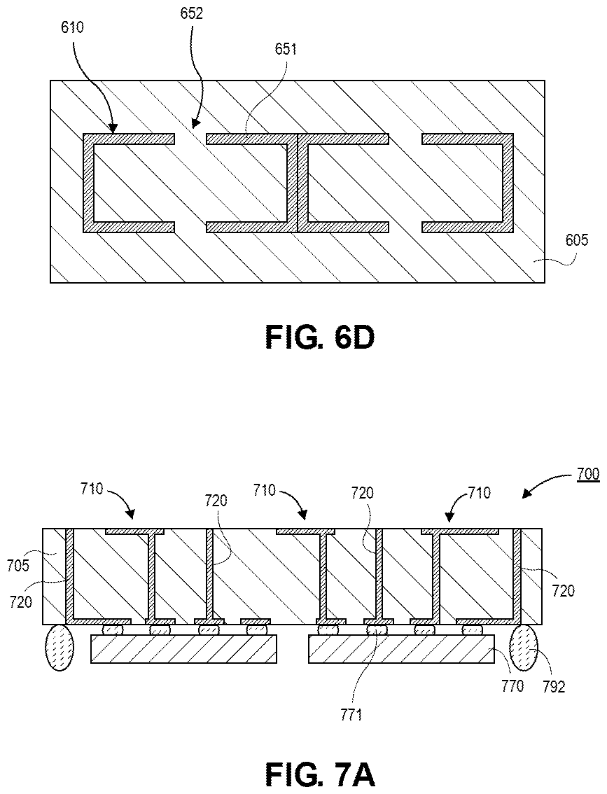

Referring now to FIG. 6A, a cross-sectional illustration of a core 605 that includes horn antennas 610 is shown, in accordance with an embodiment. In an embodiment, the horn antennas 610 may comprise a sloped ring structure 651 that passes through a thickness of the core 605. In an embodiment, the sloped ring structure 651 is a continuous ring (i.e., without any breaks in the ring structure 651), and in other embodiments the sloped ring structure 651 is non-continuous (i.e., there may be one or more breaks in the ring structure 651). In an embodiment, the slope may be at an angle θ relative to an orthogonal line to the top surface of the core 605. For example, the angle θ may be between approximately 0° and approximately 90°. In an embodiment, the angle θ may be between approximately 10° and approximately 45°. The bottom of the sloped ring structure 651 may be coupled to vias 652 and pads 653 that are formed through and over one or more buildup layers 631. In an embodiment, the die may be placed on the pads 653 to minimize the routing to the input of the horn antenna 610. Alternatively, the die may be attached to the other side of the core 605.

It is to be appreciated that the sloped ring structure 651 can be fabricated using a laser-assisted etching process, such as the one described in greater detail above. However, instead of scanning a laser across the core at an orthogonal angle, the laser is tilted the angle θ away from the orthogonal orientation. After exposure, the standard etching and plating processes of the laser-assisted etching process flow may be carried out in order to form the sloped ring structure 651.

Referring now to FIG. 6B, a plan view illustration of the top of the core 605 in FIG. 6A is shown, in accordance with an embodiment. As shown, the sloped ring structure 651 of the antenna 610 has a substantially rectangular shape. While shown as a rectangle, it is to be appreciated that the antenna 610 may have a sloped ring structure 651 with any polygonal shape. In the illustrated embodiment, the sloped ring structure 651 is shown as being a substantially continuous ring without any breaks.

Referring now to FIG. 6C, a plan view illustration of the top of the core 605 in FIG. 6A is shown, in accordance with an additional embodiment. As shown, the sloped ring structure 651 of the antenna 610 has a substantially circular shape. While shown as circular, it is to be appreciated that elliptical or other non-polygonal shapes may also be used for the ring structure 651. In the illustrated embodiment, the sloped ring structure 651 is shown as being a substantially continuous ring without any breaks.

Referring now to FIG. 6D, a plan view illustration of the top of the core 605 is FIG. 6A is shown, in accordance with an additional embodiment. As shown, the sloped ring structure 651 of the antenna 610 has a rectangular shape with breaks 652. The breaks 652 allow the portion of the core 605 within the sloped ring structure 651 to remain connected to the portion of the core 605 outside of the sloped ring structure 651. Such embodiments may simplify manufacturing, and the breaks 652 can be placed to minimize negative impacts on the performance of the antenna 610. In the illustrated embodiment, a rectangular shaped sloped ring structure 651 is shown. However, it is to be appreciated that any shaped sloped ring structure 651 may be fabricated with one or more similar breaks 652.

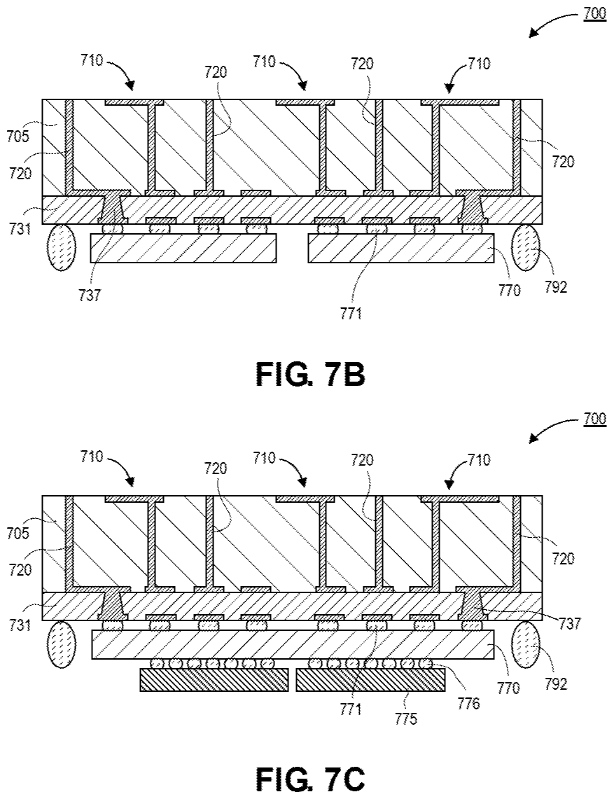

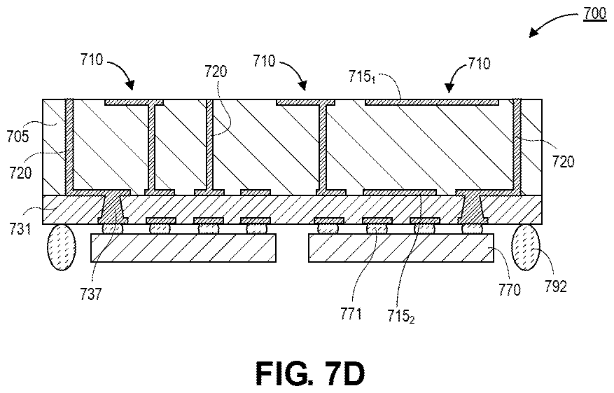

Referring now to FIG. 7A, a cross-sectional illustration of an electronic package 700 is shown, in accordance with an embodiment. In an embodiment, the electronic package 700 comprises a core 705, such as a glass core 705 or any other material capable of being patterned with a laser-assisted etching process. In an embodiment, the core 705 may comprise a plurality of vertically oriented planes 720 through a thickness of the core 705. Antennas 710 may be provided between the vertically oriented planes 720. While shown as patch antennas 710, it is to be appreciated that any antenna architecture, such as those described in greater detail herein, may be integrated with the core 705.

In an embodiment, one or more dies 770 may be coupled to the core 705. The dies 770 may be coupled to the core 705 by first level interconnects (FLIs) 771, such as solder balls, copper pillars, or the like. In an embodiment, an underfill or molding material (not shown) may surround the FLIs 771 and/or the dies 770. In an embodiment, the dies 770 may be any type of die, such as, but not limited to, a processor, a graphics processor, a system on a chip (SoC), a transceiver die, and a memory die. Second level interconnects 792 (e.g., solder balls, copper pillars, sockets, land grid array (LGA) connectors, or the like) may provide coupling to a board (not shown).

Referring now to FIG. 7B, a cross-sectional illustration of an electronic package 700 is shown, in accordance with an additional embodiment. The electronic package 700 in FIG. 7B may be substantially similar to the electronic package 700 in FIG. 7A, with the exception of the addition of a buildup layer 731 over the core 705. Vias 737 may connect features in the core 705 through the buildup layer to the FLIs 771. In an embodiment, one or more buildup layers 731 may also be provided over a bottom surface of the core 705.

Referring now to FIG. 7C, a cross-sectional illustration of an electronic package 700 is shown, in accordance with an additional embodiment. The electronic package 700 in FIG. 7C may be substantially similar to the electronic package 700 in FIG. 7B, with the exception of the die architectures. Instead of a single layer of dies 770, the die 770 is a base die and dies 775 are attached to the base die 770 by interconnects 776. In an embodiment, the dies 775 may be chiplets or other types of dies that are tiled together by the base die 770.

Referring now to FIG. 7D, a cross-sectional illustration of an electronic package 700 is shown, in accordance with an additional embodiment. In an embodiment, the dies 770 may capacitively couple to the substrate core 705. For example, one patch can either be on the die 770 or on the build up layers 731 or both. The other patch can be on the other side of core 705. Such an architecture is shown on the rightmost antenna 710. As shown, a first patch 715₁ is on the topside of the core 705, and a second patch 715₂ is on the bottom side of the core 705. The second patch 715₂ may be alternatively be provided in the buildup layer 731 or even in the die 770.

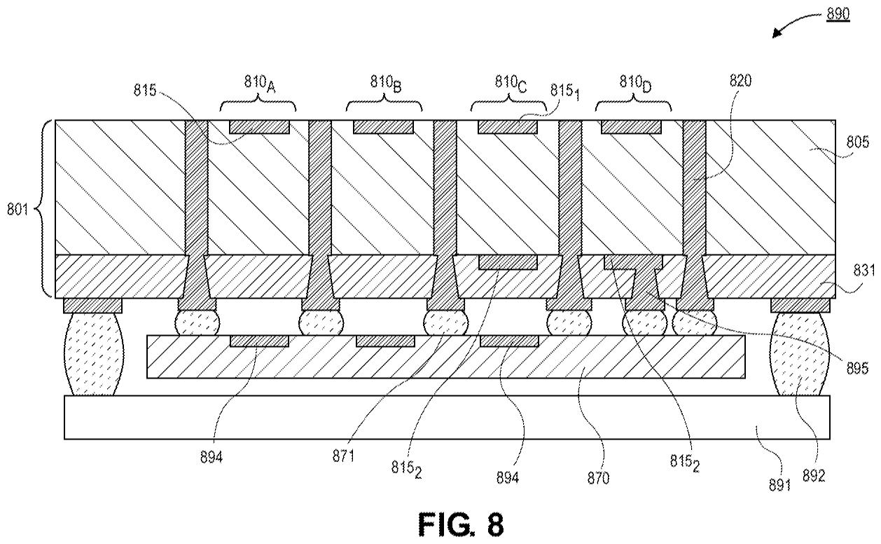

Referring now to FIG. 8, a cross-sectional illustration of an electronic system 890 is shown, in accordance with an embodiment. In an embodiment, the electronic system 890 comprises a board 891, such as a printed circuit board (PCB). The board 891 may be coupled to a package substrate 801 by interconnects 892. The interconnects 892 may be solder balls, sockets, or the like. In an embodiment, a die 870 is coupled to the package substrate 801 by FLIs 871.

In an embodiment, the package substrate 801 may comprise a core 805 with buildup layers 831. In an embodiment, the core 805 may comprise one or more antennas 810. For example, a first antenna 810A and a second antenna 810E have the die 870 directly coupled to the patch 815 (e.g., by patch 894 embedded in the die 870). In an embodiment, a third antenna 810c may have a plurality of patches 8151, 8152, and 894. In yet another embodiment, the die 870 is conductively coupled to a patch 8152 by a via 895. In an embodiment, the antennas 810 may be isolated from each other by vertically oriented planes 820. The vertically oriented planes 820 may pass through an entire thickness of the core 805, or pass partially through the entire thickness of the core 805. The antennas 810 and the vertically oriented planes 820 may have any configuration in accordance with embodiments described herein.

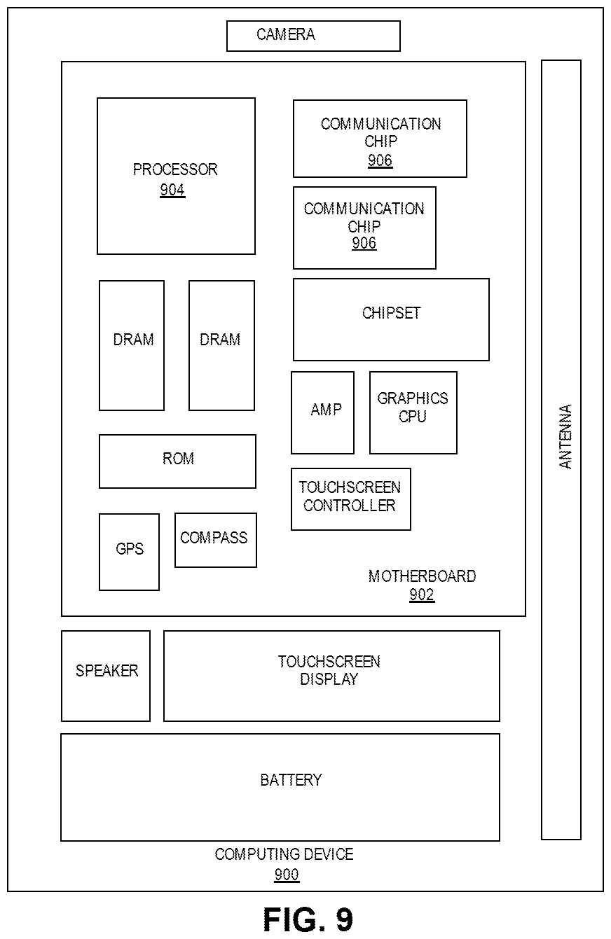

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package that comprises a package substrate with a core that is patterned with a laser-assisted etching process to form isolated antennas embedded in the core, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package that comprises a package substrate with a core that is patterned with a laser-assisted etching process to form isolated antennas embedded in the core, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core with a first surface and a second surface; a first conductive plane into the core, wherein the first conductive plane is substantially orthogonal to the first surface; a second conductive plane into the core, wherein the second conductive plane is substantially orthogonal to the first surface; and an antenna on the core, wherein the antenna is between the first conductive plane and the second conductive plane.

Example 2: the package substrate of Example 1, wherein the antenna is a patch antenna.

Example 3: the package substrate of Example 2, wherein the patch antenna comprises a patch on the first surface of the core.

Example 4: the package substrate of Example 1, wherein the antenna is a stacked patch antenna.

Example 5: the package substrate of Example 4, wherein the stacked patch antenna comprises a first patch on the first surface of the core and a second patch on the second surface of the core.

Example 6: the package substrate of Example 1, wherein the antenna is a monopole antenna that extends through the core.

Example 7: the package substrate of Example 1, wherein the antenna is a horn antenna.

Example 8: the package substrate of Example 7, wherein the horn antenna comprises a gap in a horn structure.

Example 9: the package substrate of Examples 1-8, wherein the first conductive plane and the second conductive plane extend through an entire thickness of the core.

Example 10: the package substrate of Examples 1-9, wherein the first conductive plane and the second conductive plane extend partially through an entire thickness of the core.

Example 11: the package substrate of Examples 1-10, further comprising: a third conductive plane into the core, wherein the third conductive plane is substantially orthogonal to the first surface and intersects the first conductive plane and the second conductive plane; and a fourth conductive plane into the core, wherein the fourth conductive plane is substantially orthogonal to the first surface and intersects the first conductive plane and the second conductive plane, wherein the antenna is between the third conductive plane and the fourth conductive plane.

Example 12: a package substrate, comprising: a core with a first surface and a second surface; a first antenna on a first recessed surface of the core, wherein the first recessed surface is a first distance from the first surface; and a second antenna on a second recessed surface of the core, wherein the second recessed surface is a second distance from the first surface that is different than the first distance.

Example 13: the package substrate of Example 12, further comprising: sloped sidewalls from the first surface to the first recessed surface, and sloped sidewalls from the first surface to the second recessed surface.

Example 14: the package substrate of Example 12 or Example 13, further comprising: a conductive plane between the first antenna and the second antenna, wherein the conductive plane is substantially orthogonal to the first surface of the core.

Example 15: the package substrate of Examples 12-14, wherein the first antenna and the second antenna are the same type of antenna.

Example 16: the package substrate of Examples 12-14, wherein the first antenna and the second antenna are different types of antennas.

Example 17: the package substrate of Example 16, wherein the first antenna is a patch antenna, and wherein the second antenna is a stacked patch antenna.

Example 18: a package substrate, comprising: a core with a first surface and a second surface; and a horn antenna embedded in the core, wherein the horn antenna comprises: a substantially ring shaped conductive plane with a first interior dimension at the first surface of the core and a second interior dimension at the second surface of the core.

Example 19: the package substrate of Example 18, wherein conductive plane comprises a sloped portion between the first surface of the core and the second surface of the core.

Example 20: the package substrate of Example 18 or Example 19, wherein the ring shaped conductive plane comprises a gap, wherein the gap allows for a portion of the core within the ring to be connected to a portion of the core outside of the ring.

Example 21: the package substrate of Examples 18-20, wherein the ring shaped conductive plane is rectangular.

Example 22: the package substrate of Examples 18-20, wherein the ring shaped conductive plane is circular.

Example 23: an electronic system, comprising: a board; a package substrate coupled to the board, wherein the package substrate comprises: a core with a first surface and a second surface; a first conductive plane into the core, wherein the first conductive plane is substantially orthogonal to the first surface; a second conductive plane into the core, wherein the second conductive plane is substantially orthogonal to the first surface; and an antenna on the core, wherein the antenna is between the first conductive plane and the second conductive plane; and a die coupled to the package substrate.

Example 24: the electronic system of Example 23, wherein the antenna is a patch antenna, a stacked patch antenna, a monopole antenna, or a horn antenna.

Example 25: the electronic system of Example 23 or Example 24, wherein the first conductive plane and the second conductive plane have hourglass shaped cross-sections.

What is claimed is:

1. A package substrate, comprising:
a core with a first surface and a second surface;
a first conductive plane into the core, wherein the first conductive plane is substantially orthogonal to the first surface;
a second conductive plane into the core, wherein the second conductive plane is substantially orthogonal to the first surface; and
an antenna on the core, wherein the antenna is between the first conductive plane and the second conductive plane.

2. The package substrate of claim 1, wherein the antenna is a patch antenna.

3. The package substrate of claim 2, wherein the patch antenna comprises a patch on the first surface of the core.

4. The package substrate of claim 1, wherein the antenna is a stacked patch antenna.

5. The package substrate of claim 4, wherein the stacked patch antenna comprises a first patch on the first surface of the core and a second patch on the second surface of the core.

6. The package substrate of claim 1, wherein the antenna is a monopole antenna that extends through the core.

7. The package substrate of claim 1, wherein the antenna is a horn antenna.

8. The package substrate of claim 7, wherein the horn antenna comprises a gap in a horn structure.

9. The package substrate of claim 1, wherein the first conductive plane and the second conductive plane extend through an entire thickness of the core.

10. The package substrate of claim 1, wherein the first conductive plane and the second conductive plane extend partially through an entire thickness of the core.

11. The package substrate of claim 1, further comprising:
a third conductive plane into the core, wherein the third conductive plane is substantially orthogonal to the first surface and intersects the first conductive plane and the second conductive plane; and
a fourth conductive plane into the core, wherein the fourth conductive plane is substantially orthogonal to the first surface and intersects the first conductive plane and the second conductive plane, wherein the antenna is between the third conductive plane and the fourth conductive plane.

12. A package substrate, comprising:
a core with a first surface and a second surface;
a first antenna on a first recessed surface of the core, wherein the first recessed surface is a first distance from the first surface; and
a second antenna on a second recessed surface of the core, wherein the second recessed surface is a second distance from the first surface that is different than the first distance.

13. The package substrate of claim 12, further comprising:
sloped sidewalls from the first surface to the first recessed surface, and sloped sidewalls from the first surface to the second recessed surface.

14. The package substrate of claim 12, further comprising:
a conductive plane between the first antenna and the second antenna, wherein the conductive plane is substantially orthogonal to the first surface of the core.

15. The package substrate of claim 12, wherein the first antenna and the second antenna are the same type of antenna.

16. The package substrate of claim 12, wherein the first antenna and the second antenna are different types of antennas.

17. The package substrate of claim 16, wherein the first antenna is a patch antenna, and wherein the second antenna is a stacked patch antenna.

18. A package substrate, comprising:
a core with a first surface and a second surface; and
a horn antenna embedded in the core, wherein the horn antenna comprises:
a substantially ring shaped conductive plane with a first interior dimension at the first surface of the core and a second interior dimension at the second surface of the core.

19. The package substrate of claim 18, wherein conductive plane comprises a sloped portion between the first surface of the core and the second surface of the core.

20. The package substrate of claim 18, wherein the ring shaped conductive plane comprises a gap, wherein the gap allows for a portion of the core within the ring to be connected to a portion of the core outside of the ring.

21. The package substrate of claim 18, wherein the ring shaped conductive plane is rectangular.

22. The package substrate of claim 18, wherein the ring shaped conductive plane is circular.

23. An electronic system, comprising:
a board;
a package substrate coupled to the board, wherein the package substrate comprises:
a core with a first surface and a second surface;
a first conductive plane into the core, wherein the first conductive plane is substantially orthogonal to the first surface;
a second conductive plane into the core, wherein the second conductive plane is substantially orthogonal to the first surface; and
an antenna on the core, wherein the antenna is between the first conductive plane and the second conductive plane; and
a die coupled to the package substrate.

24. The electronic system of claim 23, wherein the antenna is a patch antenna, a stacked patch antenna, a monopole antenna, or a horn antenna.

25. The electronic system of claim 23, wherein the first conductive plane and the second conductive plane have hourglass shaped cross-sections.
